(19) United States
(12) Patent Application Publication
(10) Pub. No.: US 2006/0022273 A1
(43) Pub. Date: Feb. 2, 2006

(54) System and method for assembly of semiconductor dies to flexible circuits

(76) Inventor: David Halk, Langhorne, PA (US)

Correspondence Address: MYERS & KAPLAN, INTELLECTUAL PROPERTY LAW, L.L.C., 1899 POWERS FERRY ROAD, SUITE 310, ATLANTA, GA, 30339, US

(21) Appl. No.: 11/185,062

(22) Filed: Jul. 20, 2005

Related U.S. Application Data
(60) Provisional application No. 60/592,878, filed on Jul. 30, 2004.

(51) Int. Cl. H01L 23/62

(52) U.S. Cl. 257/355

(57) ABSTRACT

A system and method for assembly of semiconductor dies to flexible circuits, wherein the present invention utilizes UV release tape as a temporary, removable carrier for precisely aligning, and maintaining the alignment of, a semiconductor die, and more specifically, the interconnecting pads thereof, with the conducting leads of a flexible circuit; thereby, expediting subsequent permanent affixation of same via thermo-sonic TAB bonding processes, or the like.

### PRIORITY CLAIM

To the fullest extent permitted by law, the present non-provisional patent application claims priority to and the full benefit of provisional patent application entitled “System and Method for Assembly of Semiconductor Dies to Flexible Circuits” filed on Jul. 30, 2004, having assigned Ser. No. 60/592,878.

### TECHNICAL FIELD

The present invention relates generally to die and substrate attachment processes, and more specifically to a system and method for assembly of semiconductor dies to flexible circuits. The present invention is particularly advantageous for its ability to temporarily affix a semiconductor die (i.e., such as those of inkjet print heads) to a flexible circuit, and thereby maintain alignment of the interconnecting leads and/or pads of same for subsequent permanent affixation via thermo-sonic bonding processes or any other suitable bonding process.

### BACKGROUND OF THE INVENTION

Assembly of semiconductor dies, or other selected components, to flexible circuits may be accomplished through highly customized and dedicated machinery that incorporate two different semiconductor interconnecting machine processes.

Specifically, most such machinery integrate a die attach machine and a thermo-sonic tape automated bonding (TAB) machine, wherein the die attach machine is utilized to align the interconnect pads of the semiconductor, or other component, to the conductive leads of the flexible circuit, and wherein a downstream thermo-sonic TAB bonding process is subsequently utilized to permanently attach same. However, the custom machinery utilized to implement such processes is often unduly expensive and results in previously purchased, and fully-operable, “stand-alone” TAB machines becoming unnecessarily obsolete.

Therefore, it is readily apparent that there is a need for a system and method for assembly of semiconductor dies to flexible circuits, wherein the present invention provides a temporary, removable carrier for stabilizing and maintaining the precise alignment and placement of a semiconductor die on a flexible circuit via a standard die attach machine processes; thereby facilitating subsequent thermo-sonic TAB bonding processes on dedicated or stand-alone TAB machines.

### BRIEF SUMMARY OF THE INVENTION

Briefly described, in a preferred embodiment, the present invention overcomes the above-mentioned disadvantages and meets the recognized need for such an invention by providing a system and method for assembly of semiconductor dies to flexible circuits, wherein the present invention utilizes UV release tape as a temporary, removable carrier for precisely aligning, and maintaining the alignment of, a semiconductor die, and more specifically, the interconnecting pads thereof, with the conducting leads of a flexible circuit; thereby, expediting assemblage and permanent affixation of same via stand-alone TAB machines or other suitable bonding processes.

According to its major aspects and broadly stated, the present invention in its preferred form is a system and method for assembly of semiconductor dies to flexible circuits, comprising, in general, UV release tape and associated application and curing processes, semiconductor die and flexible circuit alignment and engagement processes, and conventional thermo-sonic TAB bonding processes.

More specifically, the present invention is a system and method for assembly of semiconductor dies to flexible circuits, wherein a strip of UV release tape, preferably applied to the back of the flexible circuit, enables the temporary attachment of a semiconductor die thereto. That is, a flexible circuit, preferably comprising windows or apertures intermittently disposed therethrough, receives a strip of UV release tape applied thereacross such that portions of the UV release tape are exposed or accessible through the apertures of the flexible circuit.

Thereafter, a die attach machine preferably aligns and places the semiconductor die within the windows of the flexible circuit, wherein such placement preferably ensures that the interconnecting or bond pads of the semiconductor die are appropriately aligned with the conductive leads of the flexible circuit. Accordingly, the semiconductor die placed and residing within the aperture of the flexible circuit is maintained within a selected orientation via temporary adherence of same to the portion of UV release tape exposed through the aperture.

After such temporary attachment, the semiconductor/circuit/UV release tape assembly or unit may be transported to an independent or stand-alone TAB machine for permanently affixing the interconnecting pads of the semiconductor die to the conductive leads of the flexible circuit. Alternatively, the unit may be fully fabricated on the above-described custom die attach/TAB machine, or via any other suitable bonding process.

Following the applicable bonding process, the UV release tape disposed on the completely assembled unit is exposed to UV light so as to cure the adhesive of the UV release tape; thereby, weakening the bonding strength of same and, as such, allowing the UV release tape to be easily removed from the unit without leaving adhesive residue.

Accordingly, a feature and advantage of the present invention is its ability to expedite semiconductor-and-flexible circuit bonding processes by providing a temporary removable carrier.

Another feature and advantage of the present invention is its utilization of UV release tape as a temporary removable carrier during semiconductor die attachment processes.

Still another feature and advantage of the present invention is its application of a temporary, removable carrier for stabilizing and maintaining the precise alignment and placement of a semiconductor die on a flexible circuit; thereby, facilitating bonding processes.

Yet another feature and advantage of the present invention is its application in the temporary attachment of inkjet print heads, or other components, to flexible circuits, thereby facilitating subsequent thermo-sonic TAB bonding processes.

These and other features and advantages of the present invention will become more apparent to one skilled in the art from the following description and claims when read in light of the accompanying drawings.

### BRIEF DESCRIPTION OF THE DRAWINGS

The present invention will be better understood by reading the Detailed Description of the Preferred and Alternate Embodiments with reference to the accompanying drawing figures, in which like reference numerals denote similar structure and refer to like elements throughout, and in which:

FIG. 1 is a rear view of a flexible circuit with UV release tape as contemplated in a system and method for assembly of semiconductor dies to flexible circuits according to a preferred embodiment of the present invention;

FIG. 2 is a front view of a flexible circuit with UV release tape as contemplated in a system and method for assembly of semiconductor dies to flexible circuits according to a preferred embodiment of the present invention, and shown in use; and,

FIG. 3 is a side view of an exemplary method of assembly and manufacture of a flexible circuit with a semiconductor die utilizing the UV release tape processes of the present invention.

### DETAILED DESCRIPTION OF THE PREFERRED AND ALTERNATIVE EMBODIMENTS

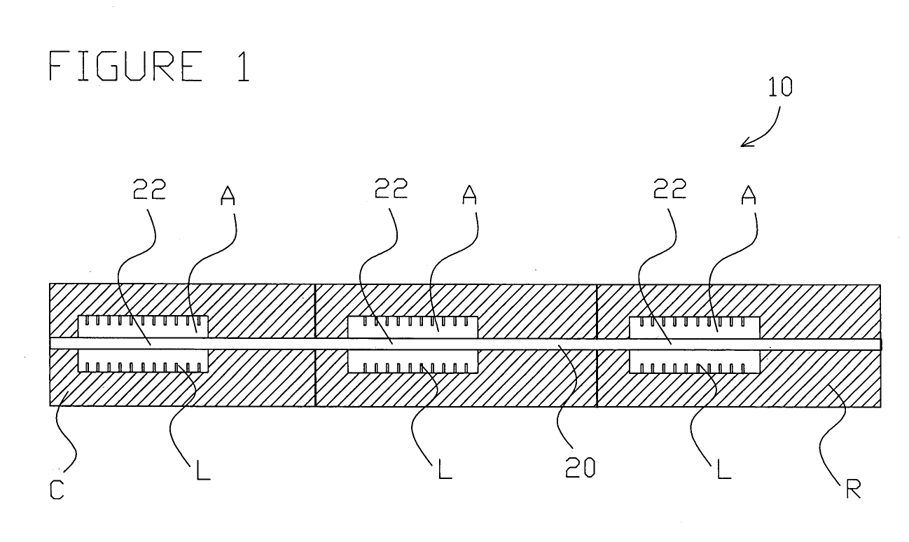

In describing the preferred and alternate embodiments of the present invention, as illustrated in FIGS. 1-3, specific terminology is employed for the sake of clarity. The invention, however, is not intended to be limited to the specific terminology so selected, and it is to be understood that each specific element includes all technical equivalents that operate in a similar manner to accomplish similar functions.

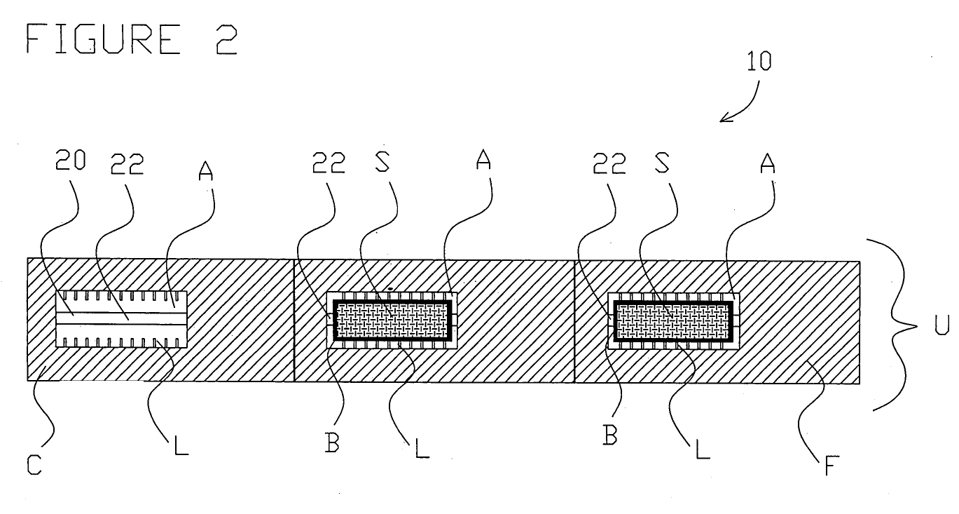

Referring now to FIGS. 1-2, the present invention in a preferred embodiment is a system and method 10 for assembly of semiconductor dies to flexible circuits, comprising UV release tape 20 and associated application and curing processes, semiconductor die and flexible circuit alignment and engagement processes, and conventional thermo-sonic TAB bonding processes.

Referring now more specifically to FIG. 1, conventional flexible circuit C is presented as a continuous tape comprising a plurality of windows or apertures A intermittently disposed therethrough, wherein each aperture A comprises a plurality of conductive leads L extending from the peripheral edges thereof toward the center of each such aperture A. However, it should be recognized that the present invention may be applied to any suitable flexible circuit adapted to receive semiconductor dies or other components.

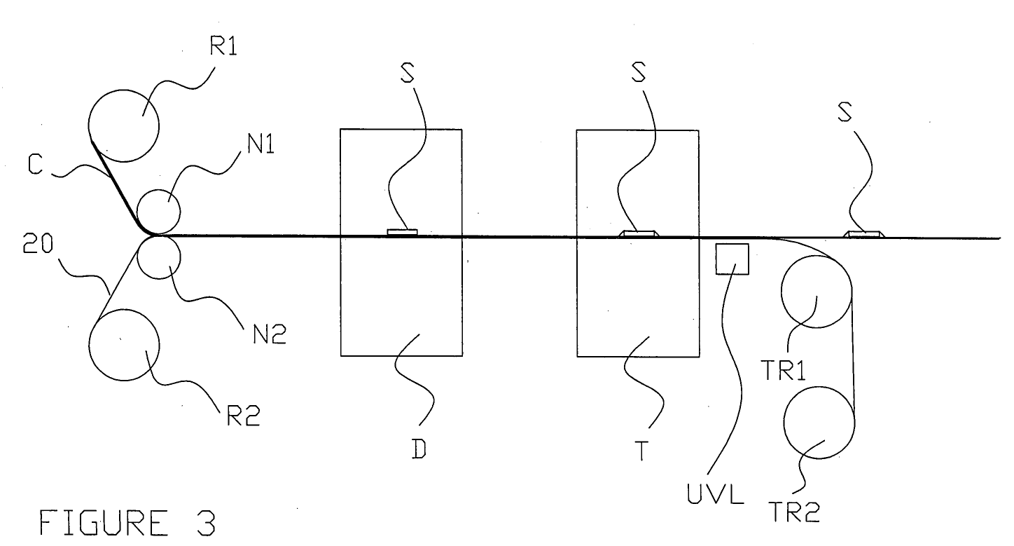

Preferably, a suitably-sized strip of UV release tape 20 (i.e., preferably approximately 1.5 mm in width) is applied to rear portion R of flexible circuit C such that portions or sections 22 of UV release tape 20 are exposed or accessible through apertures A of flexible circuit C. Specifically, UV release tape 20 is preferably applied across the length of flexible circuit C, and oriented such that UV release tape 20 approximately bifurcates each aperture A of flexible circuit C. Although any suitable method of application may be utilized to apply UV release tape 20 to flexible circuit C, the present invention contemplates automated processes for efficiency, as more fully described hereinbelow with reference to FIG. 3. Alternatively, UV release tape 20 may be selectively manually applied to any length of flexible circuit C.

With specific reference now to FIG. 2, illustrated therein is the forward face F of flexible circuit C. Following application of UV release tape 20 to flexible circuit C, a standard die attach machine places, via machine vision and precise motion control, semiconductor dies S within apertures A of flexible circuit C such that interconnecting or bond pads B of semiconductor dies S are appropriately and precisely aligned with or over respective conductive leads L of flexible circuit C. Upon precise alignment of bond pads B of semiconductor dies S with conductive leads L of flexible circuit C, die attach machine preferably applies a placement force of less than approximately 100 grams over semiconductor die S; thereby, preferably temporarily affixing semiconductor dies S to respective portions or sections 22 of UV release tape 20 exposed through apertures A of flexible circuit C. As such, and as a result of the inherent tackiness of UV release tape 20, bond pads B of semiconductor dies S are maintained in an aligned orientation relative to conductive leads L of flexible circuit C.

Accordingly, following such temporary attachment of semiconductor dies S to sections 22 of UV release tape 20, semiconductor/circuit/UV release tape assembly or unit U may be transported to an independent or stand-alone TAB machine for permanently affixing bond pads B of semiconductor dies S to associated conductive leads L of flexible circuit C. Alternatively, unit U may be fully fabricated on a combined custom die attach/TAB machine, or via any other suitable bonding process. It should be recognized that the selected type of UV release tape 20 should preferably be able to withstand the elevated temperatures of conventional thermo-sonic bonding processes (i.e., approximately 250° C. to approximately 300° C.).

Following the applicable bonding process, UV release tape 20 disposed on assembled unit U is exposed to UV light so as to cure the UV sensitive adhesive of UV release tape 20; thereby, weakening the bonding strength of same and, as such, allowing UV release tape 20 to be easily removed from unit U without leaving behind any residue on semiconductor dies S or flexible circuit C. Preferably, UV release tape 20 is exposed to UV light for a manufacturer's recommended length of time at the designated wavelength for effective release and/or degradation of the adhesive thereof.

With specific reference now to FIG. 3, although any suitable method of application may be utilized to apply UV release tape 20 to flexible circuit C, the present invention contemplates an automated process for efficiency. Specifically, the automated process of the present invention could utilize continuous streams of both flexible circuit C and UV release tape 20, wherein each such stream may be supplied by stock rolls R1, R2, respectively, and wherein each such stream may be contemporaneously passed through nip rolls N1, N2; thereby, temporarily laminating or adhering UV release tape 20 to flexible circuit C. The temporarily adhered flexible circuit C and UV release tape 20 may then be conveyed through die attach machine D for placement of semiconductor dies S to UV release tape 20 of flexible circuit C, and thereafter subjected to thermo-sonic TAB machine T for permanent affixation of dies S to circuit C. Following the applicable bonding process, assembled unit U may then be indexed forward and exposed to UV light UVL; thus, delaminating UV release tape 20 from unit U. The removed or delaminated UV release tape 20 may then be systematically collected by take-up rolls TR1, TR2, as removed from unit U.

It is contemplated that the present invention may be utilized in the assembly and attachment of inkjet print heads, or other components, to flexible circuits.

It is contemplated in an alternate embodiment that other light-sensitive release tapes may be utilized as temporary, removable carriers, wherein appropriate spectrums of light, other than UV light, may be utilized to weaken the bonding strength of same.

It is contemplated in another alternate embodiment that other types of tapes or removable carriers may be utilized instead of UV release tape 20, wherein such alternate carriers may include, without limitation, thermally-sensitive release tapes, pressure-sensitive release tapes, protective cover tapes, gel-based or gel-pack surface tension and adhesion tapes, and/or tacky or high-friction plastic films, strips or strands, such as, for exemplary purposes only, cellophanes, urethanes, ethyl methyl acrylates, ethylene vinyl acetates, ethylene methacrylic acids, polyolefins, and blends thereof.

Having thus described exemplary embodiments of the present invention, it should be noted by those skilled in the art that the within disclosures are exemplary only, and that various other alternatives, adaptations, and modifications may be made within the scope of the present invention. Accordingly, the present invention is not limited to the specific embodiments illustrated herein, but is limited only by the following claims.

What is claimed is:

1. A method for assembly of a semiconductor die to a flexible circuit, said method comprising the steps of:
a. applying a temporary carrier to the flexible circuit; and, b. placing the semiconductor die in releasable
engagement with said temporary carrier.

2. The method of claim 1, wherein said temporary carrier is a release tape.

3. The method of claim 1, wherein said temporary carrier is a light-sensitive release tape.

4. The method of claim 1, wherein said temporary carrier is a UV release tape.

5. The method of claim 1, wherein said temporary carrier is selected from the group consisting of release tapes, light-sensitive release tapes, thermally-sensitive release tapes, pressure-sensitive release tapes, protective cover tapes, gel-based tension and adhesion tapes, gel-pack surface tension and adhesion tapes, plastic films, plastic strips, plastic strands, and combinations thereof.

6. The method of claim 1, wherein said step a. further comprises the step of applying said temporary carrier to the flexible circuit such that said temporary carrier at least partially intersects an aperture of the flexible circuit.

7. The method of claim 1, wherein said step b. further comprises the step of placing the semiconductor die within the aperture of the flexible circuit such that the semiconductor die resides in releasable engagement with said temporary carrier intersecting the aperture.

8. The method of claim 1, further comprising step c.: bonding the semiconductor die to the flexible circuit via thermo-sonic tape automated bonding processes.

9. The method of claim 1, further comprising step c.: bonding the semiconductor die to the flexible circuit.

10. The method of claim 9, further comprising step d.: removing said temporary carrier from the flexible circuit and the semiconductor die.

11. A method for assembly of a semiconductor die to a flexible circuit, said method comprising the steps of:
a. applying a light-sensitive release tape to the flexible circuit; and, b. placing the semiconductor die in releasable
engagement with said light-sensitive release tape.

12. The method of claim 11, further comprising step c.: bonding the semiconductor die to the flexible circuit via thermo-sonic tape automated bonding processes.

13. The method of claim 12, further comprising step d.: exposing said light-sensitive release tape to light so as to weaken adhesives over said light-sensitive release tape, thus allowing removal of said light-sensitive release tape from the flexible circuit and the semiconductor die.

14. The method of claim 11, wherein said temporary carrier is a UV release tape.

15. A method for assembly of a semiconductor die to a flexible circuit, said method comprising the step of:
a. forming a unit comprising said semiconductor die releasable secured to said flexible circuit via a UV release tape.

16. A device for assembly of a semiconductor die to a flexible circuit, said device comprising:
a temporary releasable carrier.

17. The device of claim 16, wherein said temporary releasable carrier is a release tape.

18. The device of claim 16, wherein said temporary releasable carrier is a light-sensitive release tape.

19. The device of claim 16, wherein said temporary releasable carrier is a UV release tape.

20. The device of claim 16, wherein said temporary releasable carrier is selected from the group consisting of release tapes, light-sensitive release tapes, thermally-sensitive release tapes, pressure-sensitive release tapes, protective cover tapes, gel-based tension and adhesion tapes, gel-pack surface tension and adhesion tapes, plastic films, plastic strips, plastic strands, and combinations thereof.

21. An apparatus for yielding a permanently bonded semiconductor die and flexible circuit, said apparatus comprising:
a flexible circuit;
a semiconductor die; and,
a light-sensitive release tape.
